(19) United States
(12) Patent Application Publication
(10) Pub. No.: US 2019/0088348 A1
(43) Pub. Date: Mar. 21, 2019

(54) MEMORY TEST CONTROL FOR STACKED DDR MEMORY

(71) Applicant: QUALCOMM Incorporated, San Diego, CA (US)

(72) Inventors: Arvind JAIN, Bangalore (IN); Nishi BHUSHAN SINGH, Bangalore (IN); Roberto AVERBUJ, San Diego, CA (US); Daniel LEWIS, San Diego, CA (US)

(21) Appl. No.: 15/887,695

(22) Filed: Feb. 2, 2018

(30) Foreign Application Priority Data
Sep. 21, 2017 (IN) 201741033496

(51) Int. Cl. G11C 29/36; G11C 29/12; G11C 29/14

(52) U.S. Cl. CPC G11C 29/36; G11C 29/14; G11C 29/12015

(57) ABSTRACT

Disclosed are methods and apparatus for implementing a memory controller, such as a bus integrated memory controller (BIMC) that includes a memory built-in-self-test (MBIST) controller or logic. The MBIST controller is configured for testing at least one memory device, such as stacked low power double data rate (LPDDR) memories in a system on a chip or similar constructions that make external testing of the memory device difficult. The MBIST controller may be implemented within a standard memory controller and includes a memory translation logic configured to translate signals for testing the at least one memory device into signals in a format that is usable by the at least one memory device, where the translation logic serves to effectuate a memory representation.

### CROSS-REFERENCE TO RELATED APPLICATIONS

The present Application for patent claims priority to pending Indian Application No. 201741033496, titled “MEMORY TEST CONTROL FOR STACKED DDR MEMORY” filed Sep. 21, 2017, and assigned to the assignee hereof and hereby expressly incorporated by reference herein as if fully set forth below and for all applicable purposes.

### BACKGROUND

### Field

The present disclosure relates to a memory test control for double data rate (DDR) memories, and more particularly to memory test control for stacked DDR dynamic random access memories (DRAM) within a system on a chip (SoC) to run memory tests on the stacked DDR memories.

### Background

In particular SoC's and similar structures, DDR memory, such as Low Power DDR memory (e.g., LPDDR4), is stacked within the SoC. Many DDR memory manufacturers provide that memory devices be tested according to particular tests, which are typically provided by the manufacturer. In the case of stacked memories, manufacturers also recommend that such memories be testable according to the complete memory tests. In such cases of stacked SoC's, however, known interfaces to test DDR memory devices at speed are not available, which makes testing according to the suggested tests difficult, and it is not easy to distinguish a location of the causes of system failures should they occur. Accordingly, methods and apparatus for meeting test requirements that include the use of a built in test controller that is compatible with Joint Electron Device Engineering Council (JEDEC) standards and supports the particular DDR interface, such as a Low Power DDR 4 (LPDDR4) interface, in order to ensure the integrity of stacked DDR memories.

### SUMMARY

Various features, apparatus and methods described herein provide a programmable built-in-self-tester (BIST) in a memory controller.

According to an aspect, an apparatus is disclosed that may be implemented within or as a mobile station, for example. The apparatus includes a memory controller (MC) that includes a memory built-in self-test (MBIST) configured for testing at least one memory device. The MBIST includes a memory translation logic configured to translate signals for testing the at least one memory device into signals in a format of the at least one memory device.

According to another aspect, a method for testing a memory device is disclosed. The method includes initiating an MBIST operation within a memory controller (MC) including placing an MBIST logic in communication with the memory device. The method further includes translating one or more commands and data from the MBIST logic with a memory translation logic for testing the memory device into signals in a format that are compatible with the memory device.

In yet another aspect, an apparatus is disclosed comprising a memory receiving one or more instructions for testing the memory. The instructions include a command for initiating an MBIST operation within a memory controller (MC) including placing an MBIST logic in communication with the memory device; and a command for translating one or more commands and data from the MBIST logic with a memory translation logic for testing the memory device into signals in a format that are compatible with the memory device.

According to another aspect, a non-transitory computer-readable medium storing computer-executable code is disclosed. The medium includes code for causing a computer to implement within a memory controller (MC) a memory built-in self-test (MBIST) function configured for testing at least one memory device. Furthermore, the medium includes code for translating, using the MBIST function, signals for testing the at least one memory device into signals in a format that is used by the at least one memory device.

### DRAWINGS

Various features and advantages may become apparent from the detailed description set forth below when taken in conjunction with the drawings in which like reference characters identify correspondingly throughout.

FIG. 1 illustrates an example of a memory package and a memory controller (MC), such as a bus integrated memory controller (BIMC) within a System on a Chip structure.

FIG. 2 illustrates an exemplary block diagram of a MC (e.g., BIMC) including a memory built-in self-test (MBIST) logic coupled between a bus and a memory device.

FIG. 3 illustrates an exemplary block diagram of the MC with an MBIST logic that is illustrated in FIG. 2.

FIG. 4 illustrates an exemplary block diagram of the MBIST logic illustrated in FIG. 3.

FIG. 5 illustrates an exemplary block diagram of at least a memory representation portion of the MBIST core logic illustrated in FIG. 4.

FIG. 6 illustrates an exemplary translation module that may be utilized within the memory representation within the MBIST logic of FIGS. 4 and 5.

FIG. 7 illustrates a timing diagram of command data (e.g., CA/CS/CKE signals) within the MBIST logic and at an input of the memory where the timing frequency of the MBIST is a fraction of the memory operating frequency.

FIG. 8 illustrates a timing diagram of DQ data within the MBIST logic and at an input of the memory where the timing frequency of the MBIST logic is a fraction of the memory operating frequency.

FIGS. 9 and 10 illustrate phase control including phase shifting according to an aspect of the present disclosure.

FIG. 11 illustrates a flow diagram of an exemplary method for implementing and/or operating an MBIST logic in an MC.

FIG. 12 illustrates a flow diagram of another exemplary method for implementing and/or operating an MBIST logic in an MC.

FIG. 13 illustrates a conceptual diagram illustrating an example of a hardware implementation for an exemplary User Equipment (UE) or mobile station in which the present MC may be implemented.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Memory built in self-test controllers or logic (e.g., MBISTs) ideally should support all of the various custom operations required to support custom testing and other algorithms that may be requested by different memory suppliers. DDR memory devices, and LPDDR4 memory devices in particular, employed with System on a Chip (SoC) devices, such as DDRs stacked with a SoC, typically have memory supplier imposed requirements that mandate extensive external memory testing. While a DDR is independently tested by a memory supplier, when DDRs are stacked there are situations where no interface to test such configured DDR memories at speed will be available. Accordingly, the presently disclosed methods and apparatus provide for testing of stacked DDR memories with an MBIST that may fully support various testing algorithms provided by different memory suppliers. Additionally the presently disclosed methods and apparatus provide an MBIST that may be integrated within existing BIMC designs with minimal interface changes. The present methods and apparatus further provide an MBIST design capable of affording custom operation sets and custom algorithms for various types of DDR memories, including LPDDR4 memories, through the use of at least a translation finite state machine (FSM) or similar logic.

Yet further, the present methods and apparatus provides doubled command/address (CA) bus and data bus support, which enables 1 to 2 ratio (i.e., 1:2 mode for operation) BIMC support such that the memory test controller (e.g., an interface of the memory test controller) may be run at half of the frequency of DDR memory. Coextensive with the 1:2 mode, the present methods and apparatus also provide for phase control support for this 1:2 mode. Namely, a programmable logic or mechanism for phase swapping may be provided to achieve a one memory cycle shift for both the CA and data buses. Still further, the presently disclosed methods and apparatus afford different data mask (DM) sequence support where different Group write-enable and swapping mechanisms are utilized to achieve different DM sequences that may be required for custom algorithms.

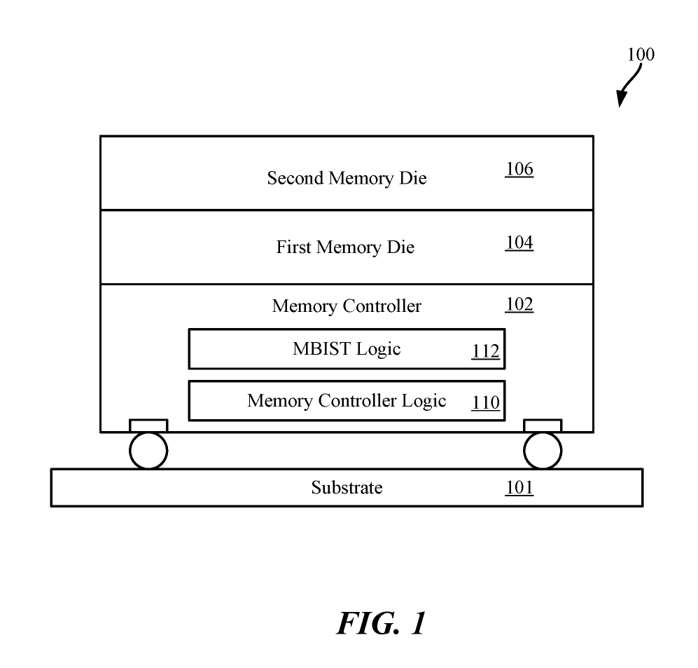

For contextualization, FIG. 1 illustrates an example of a package structure comprising a SoC system, for example, with stacked memory devices featuring a memory controller with an MBIST logic for testing the memory devices and running self-diagnosis tests to check the operation and/or functionality of the package. In particular, FIG. 1 illustrates a package 100 includes a substrate 101, a memory controller 102 (e.g., on an application processor die), a first memory die 104 and a second memory die 106. In an aspect, the memory controller 102 may be located on top of the substrate 101. The memory controller 102 may include an MBIST logic 112 and a memory controller logic 110. It is noted here that although FIG. 1 illustrates an MBIST logic within the memory controller 102, the MBIST may alternatively be a test that is provided by a host via a communicative link or coupling that is, in turn, executed by the memory device or die. The first memory die 104 may be located on top of the memory controller 102 and the second memory die 106 located on top of the first memory die 104. Furthermore, in another alternative the first and second memory dies 104, 106 may also be located to the side of the memory controller 102 in a particular package configuration. In some implementations, at least one of the memories 104, 106 is a Double Data Rate Synchronous Dynamic Random Access Memory (DDR SDRAM). In other implementations the memory(s) 104, 106 is a memory configured according as a LPDDR4 memory device.

The memory controller 102 is configured for controlling access, writing, reading, and so forth for the first and second memory dies 104, 106. In some implementations, the control is performed by the memory controller logic 110. The MBIST controller or logic 112 is configured for testing at least one or more memory dies, such as the first and second memory dies 104, 106.

As will be explained in more detail later, the MBIST controller or logic 112 may be defined by one or more circuits in the memory controller 102. Similarly, the memory controller logic 110 may be defined by a one or more circuits in the memory controller 102. Although only two memory dies are shown, the package 100 may include more than two memory dies. In addition, the position of the dies may be located differently. For example, in some implementations the memory controller 102 may be located between the first memory die 104 and the second memory die 106. The memory controller 102 may also be located on top of the second memory die 106 in some implementations. The dies in package 100 may be electrically and communicatively coupled to each other by, for example, communicative coupling (e.g., chip-to-chip links) such as Through Silicon Vias (TSVs), wire bonding, and/or solder bumps in some implementations.

It is noted that the structure of FIG. 1 may be implemented within a mobile device, such a mobile station (MS), a User Equipment (UE), a cell phone, or any other mobile communicating device. Furthermore, the memory controller 102 may be part of a host, processor (e.g., an application processor), or processing circuitry of the mobile station.

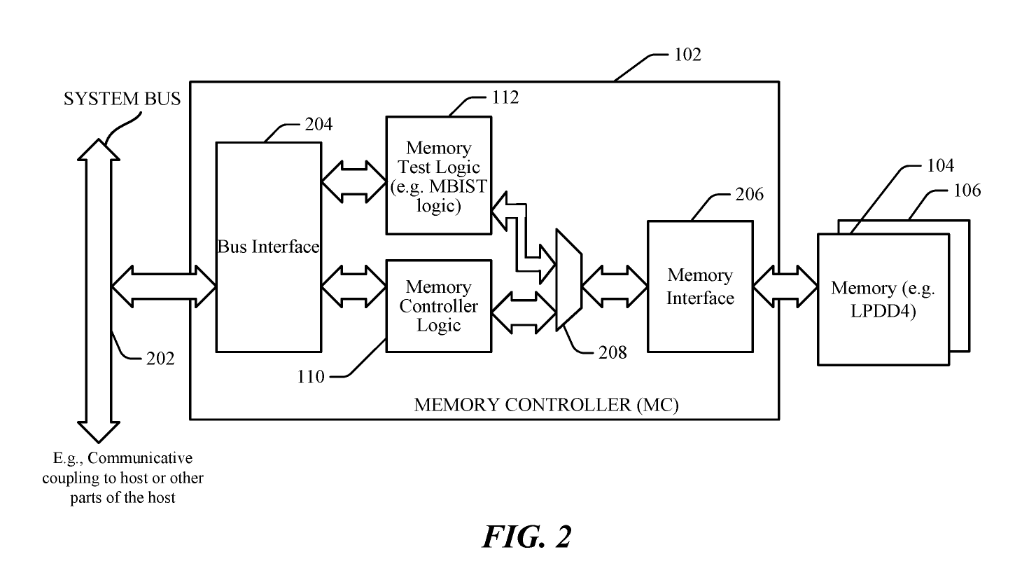

FIG. 2 illustrates an exemplary block diagram of a memory controller, such as memory controller 102. As may be seen, the memory controller 102, which may be a memory controller (MC), or in certain aspects, a bus interface memory controller (BIMC), includes the MBIST logic 112 and memory controller logic 110. As further shown in FIG. 2, the BIMC 102 is communicatively coupled to a communicative coupling or a system bus 202 configured for communication with the host or, alternatively, to other parts of the host via a bus interface 204. The memory controller 102 is also communicatively coupled to at least one memory 104 through a memory interface 206. The memory controller 102 controls the read and write operations of the memory 104. In one aspect, it is noted that the memory controller 102 may be part of a host device that is writing and reading data to the memory 104.

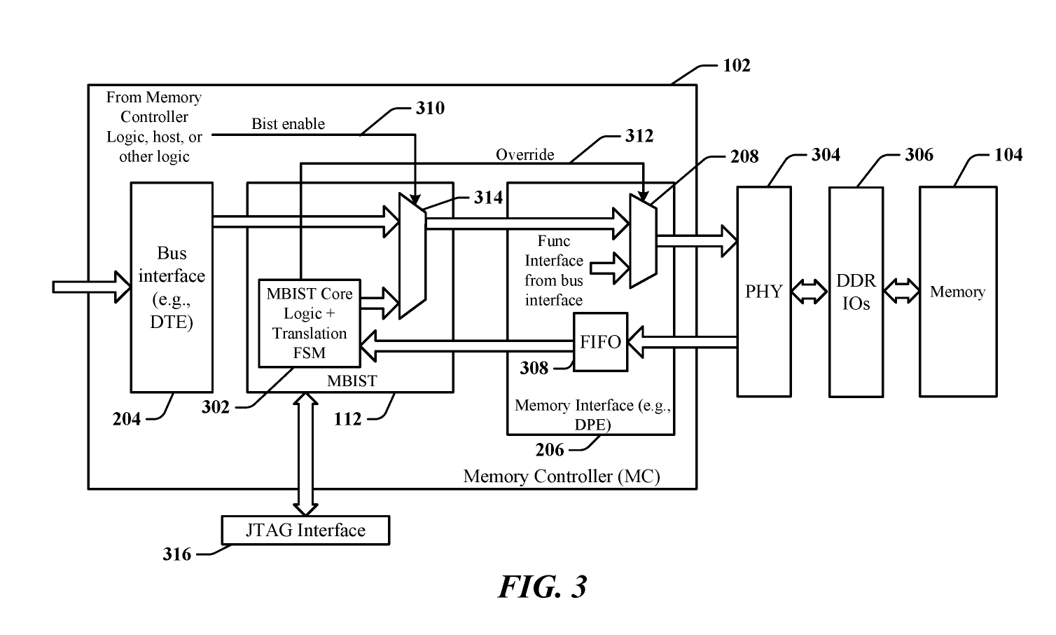

The memory test logic or MBIST logic 112 may also be coupled to the between the bus interface 204 and the memory interface 206. In order for the MBIST logic 112 to perform testing operations on the memory(s) 104, 106, the MBIST logic 112 communicates with and sends instructions in place of the memory controller logic 110. Thus, a switch interface 208 configured to selectively provide communicative coupling between the MBIST logic 112 and the memory interface 206 may be utilizing. The interface 208, according to some embodiments may be under the control of the MBIST logic 112, but the selection is not limited to such and could alternatively be effectuated by some external signal from a processor in a device or SoC employing memory controller 102. Furthermore, the switch interface 208 may be separate from the memory interface 206, as illustrated, or incorporated within the memory interface 206 as will be shown in the example of FIG. 3. It is further noted that the switch interface 208 may be a multiplexer.

The memory controller logic 110 may perform control operations on the memory 104, 106 through the memory interface 206. For example, the memory controller logic 110 may perform read and write operations on the memory 202. These read and write operations may specify the location of the memory 104, 106 where data is written to and/or where data is read from.

The MBIST logic 112 may perform testing on the memory 104, 106 through the memory interface 206. The MBIST logic 112 may perform a variety of testing operations (e.g., using different testing algorithms and/or scans) as will be discussed in more detail later. These testing operations or scans may be selectable and/or programmable. In some implementations, the MBIST logic 112 may be programmable (e.g., program the types of tests that the MBIST logic can perform) through an interface (e.g., a Joint Test Action Group (JTAG) interface). Moreover, the MBIST logic 112 may be a separate circuit from the circuit of the memory controller logic of the memory controller in some implementations.

FIG. 3 illustrates a more detailed block diagram of an exemplary implementation of memory controller 102 utilizing MBIST logic 112. It is noted that the memory controller logic 110 has been omitted in this drawing for sake of clarity.

The MBIST logic 112 is located between the bus interface 204 and the memory interface 206 within BIMC 102. A number of signals may be directly driven between the bus interface 204 and the memory interface 206. During testing, some of these signals are to be intercepted and driven with use of the MBIST logic 112 for testing the memories 104, 106. According to an aspect, the presently disclosed MBIST logic 112 provides a built-in memory test controller design that supports the extensive algorithm testing required for DDR memories, and LPDDR4 or LPDDR5 stacked memories (or similar memory devices) in particular. In one example, MBIST 112 may be configured as a LPDDR4 or LPDDR5 memory test controller that is integrated in a BIMC design (i.e., the present disclosure does not necessarily pertain solely to modification of LPDDR4 or LPDDR5 memory BIMC's but could be utilized in any of a number of memory BIMC architectures such as an LPDDR2 BIMC architecture, for example).

As illustrated in FIG. 3, the MBIST logic 112 may feature an MBIST core logic 302. This core logic 302 may further include a translation finite state machine (FSM) or similar structure or functionality for translating commands and instructions to be able to interface with the memory interface 206 and the various memory connections (e.g., a PHY interface 304, DDR Input/output 306) and the memory itself (e.g., 104). The MBIST core logic 302 is further configured with custom operation sets and custom algorithms for a particular memory to be tested, such as an LPDDR4 memory. The logic further includes a translation state machine that translates MBIST signals into compatible commands for the memory to be tested. The translation state machine effectuates a memory representation creation to make the tool think that the memory is local, acting like a fake memory. The translation state machine also has tasks of generating required I/O 306 and DDR PHY 304 Signals required to read and write accurately from the memory.

The memory interface 206 also includes a First in First Out (FIFO) buffer 308 that receives the DDR data read back from the PHY/memories (304/104, The FIFO 308 allows the BIST logic 302 to interface with the PHY/memories without the need to deal with synchronization of DDR data. In another aspect, it is noted that DDR memory operates at a frequency (e.g., the DDR memory interface frequency) that is higher than the typical frequency for operating the BIMC controller 102. The memory interface, however, needs to operate at a frequency commensurate with the DDR operating frequency (e.g., the DDR memory interface frequency) to properly interface with the memory. For example, the DDR operating frequency may refer to a maximum DDR memory interface frequency specified by a specification, such as LPDDR4 or LPDDR5. The present disclosure thus further provides that the interface 206 allows the MBIST 112 and MBIST logic 302 to operate at same frequency as the BIMC 102 which is about half of the DDR frequency (i.e., a 1:2 ratio). In other embodiments the frequency ratio could be greater or lesser, depending on the particular memory being tested. In one example, the present disclosure allows for testing the DDR memory at the maximum DDR memory interface frequency.

The MBIST 112 is further configured to receive a BIST or MBIST enable signal 310 to cause or trigger the system to enter into a memory test mode and to generate an override signal 312 to switch the memory interface 206 via switch 208 between MBIST signals and functional interface signals passed between the bus interface 204 and the memory interface 206 in normal operation. In certain aspects, the MBIST enable signal 310 may be received from logic within the BIMC 102, from logic or processing outside the BIMC 102. Alternatively, in some embodiments the MBIST enable signal 310 may also be generated within MBIST logic 112 itself rather than being received from an external logic or processor. The override signal 312 may be configured to be generated by the MBIST logic 302 and serves to select which input to switch or multiplexer 208 is output to the PHY/DDR I/Os/memory device; i.e., either the input from MBIST logic 112 or the normal functional interface signals from bus interface 204 during standard memory control by BIMC 102 (or other logic used in operation of the memory control).

While switching or multiplexing between the functional and memory BIST signals is within the memory interface 102 (i.e., using switch or multiplexer 208), additional switching or multiplexing, as represented by multiplexer 314, may be utilized at the output of the MBIST core logic and FSM (and, in particular, a memory representation as will be discussed later), due to requirements of particular memory and memory interface 206, as well as JEDEC specifications. The MBIST logic 112 also is configured to receive external instructions and data via a JTAG interface 316.

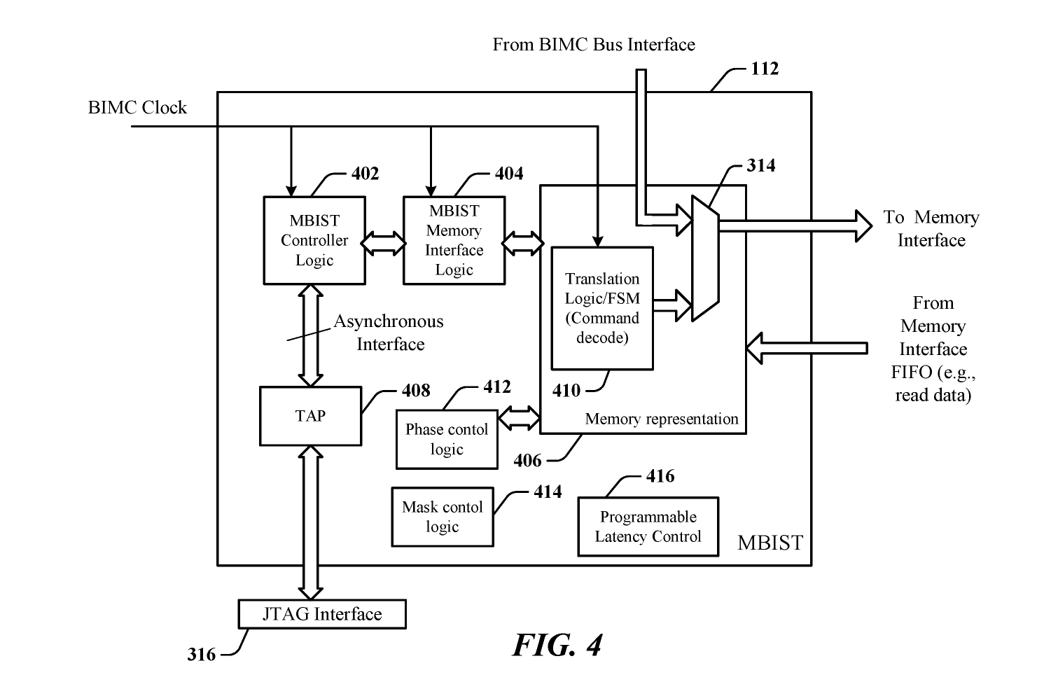

FIG. 4 illustrates a more detailed block diagram of the MBIST logic 112 shown in FIGS. 2 and 3. It is first noted that the various logic blocks or components illustrated herein may be hardcoded and fixed. In other examples, however, the logic block or components maybe configured or implemented and then connected with a memory configuration tool.

As may be seen in FIG. 4, the MBIST logic 112 (and more specifically according to a particular example, the core logic 302) may include an MBIST controller logic 402 that is clocked at the frequency of the BIMC clock. The MBIST controller logic 402 controls the operations of the MBIST logic 112 through an MBIST memory interface logic 404 that, in turn, interfaces with a memory representation transform logic or FSM 406, in particular. Since the memory device 104, 106 is external to the chip, a memory representation is created to make the memory device appear to be a local memory to the MBIST logic 112, thus acting as a type of proxy or false memory. In an aspect, it is noted that the memory representation model may contain specifications that inform an MBIST logic configuration tool the particular MBIST logic that is to be inserted or configured.

In an aspect, the MBIST core logic may be automatically generated and connected within the MBIST logic 112 by a memory configuration tool. The MBIST core logic may be thought of a consisting of the MBIST controller logic 402, the MBIST memory interface logic 404, as well as a test access port (TAP) 408. The TAP 408 is communicatively coupled with the JTAG interface 316, which may be configured as an LVTAP that is located at the top-level of the chip or SoC and is configured to communicate with various TAP modules in the system. Furthermore, selection or multiplexing between functional and MBIST signals may be performed within the memory interface.

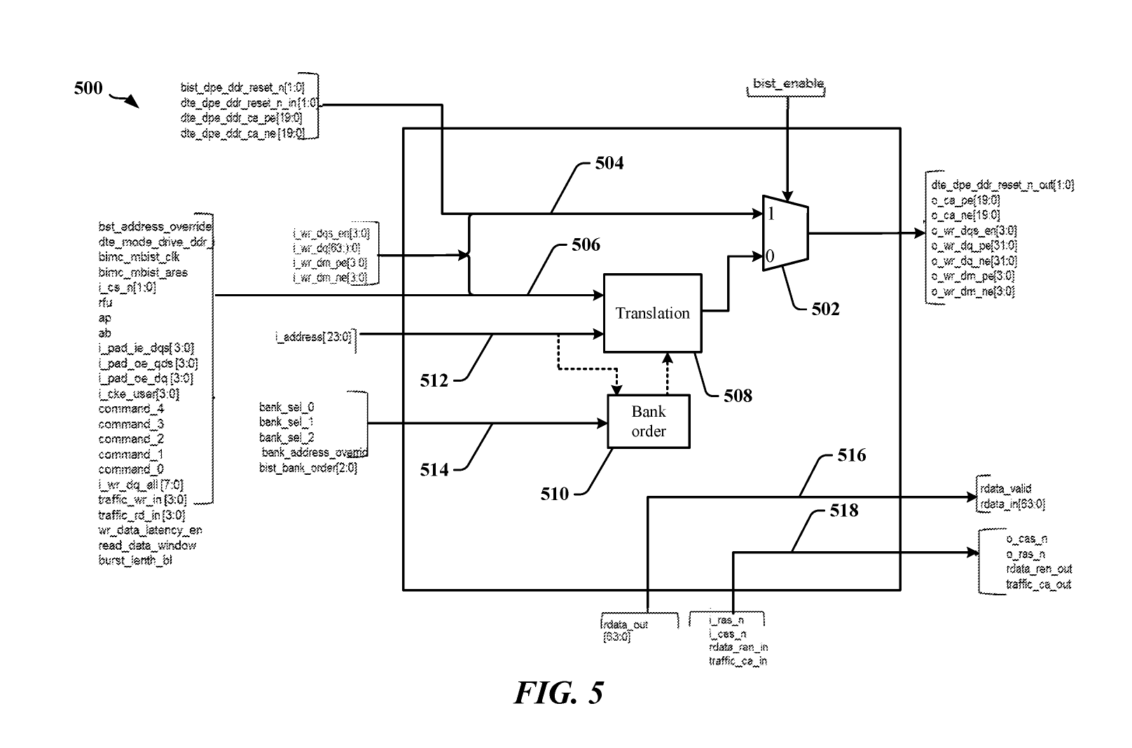

FIG. 5 illustrates a block diagram 500 of at least a portion of the memory representation or memory representation logic 406 or FSM 302 shown in FIGS. 3 and 4. As noted above, a reason for utilizing a memory representation is that the memory device does not exist in the area parsed by the MBIST logic 112, and thus this memory representation logic is used to trick the logic into identifying the memory representation as a local memory, and proceed with a regular automatic insertion of the MBIST logic 112. Additionally, the MBIST logic 112 has flexibility to create signals with different purposes, but it cannot accurately create a group of signals that matches the functionality and timing expected by the memory interface 206. Accordingly, the memory representation shown in FIG. 5 provides the functionality to the MBIST logic 112 of being able to transform and adapt the signals between the MBIST logic 112 and the memory interface 206.

As illustrated in FIG. 5 a multiplexer 502 allows selection based on the MBIST enable signal (e.g., 310) of functional signals 504 or MBIST translation signals of various command and data signals 506 input to and translated by translation block 508. The translation block 508 provides the ability to translate MBIST signals into signals that are compatible with the memory interface 206 for testing of the memory devices 104, 106. The translation block 508 also may translate based on the input of a bank order block or logic 510 operable based on a input address 512 and blank selection and ordering signals 514.

The memory representation logic portion 500 also may include pass through signals 516, 518, for signals not affected by or pertinent to the MBIST logic 112. It is further noted that the various signals illustrated as input to the memory representation logic portion 500 and output therefrom are merely exemplary and the disclosure is not intended to be limited to such.

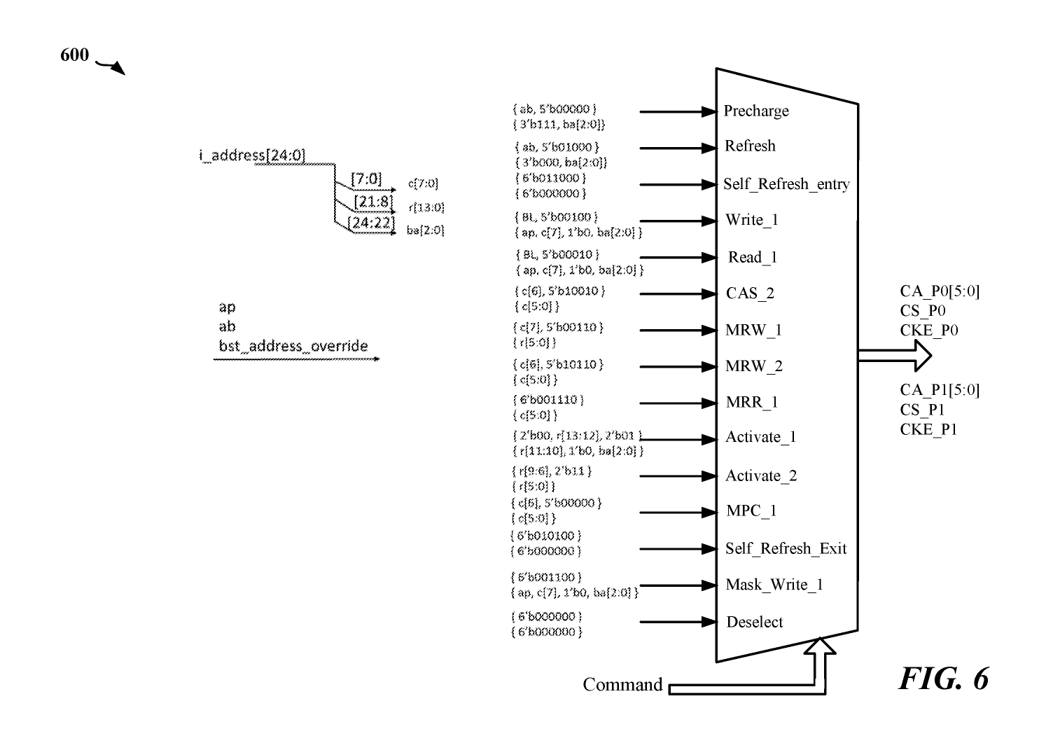

FIG. 6 illustrates a diagram of an exemplary translation module or encoder 600 that may be located within the memory representation 500 of FIG. 5. The translation module 600 is configured to take the signals between the MBIST components and logic and the memory interface 206, and adapts the timing of these signals to enable the communication back and forth between the MBIST logic 112 and memory interface 206. As an example, any MBIST requests or signals from MBIST logic 112 such as address, activate, read enable, write enable, BIST user bit, User IR bits, precharge, etc. are converted into a corresponding request in the format that is interpretable by the memory interface 206. The translation FSM and translation module 600 also carries out the tasks of generating required I/O and DDR PHY Signals required to read and write accurately from the memory devices 104, 106. According to other aspect, the translation FSM may include programmable data (DQ) and strobe (DQS) delays to meet the memory device timing (i.e., DQ and DQS timing relations).

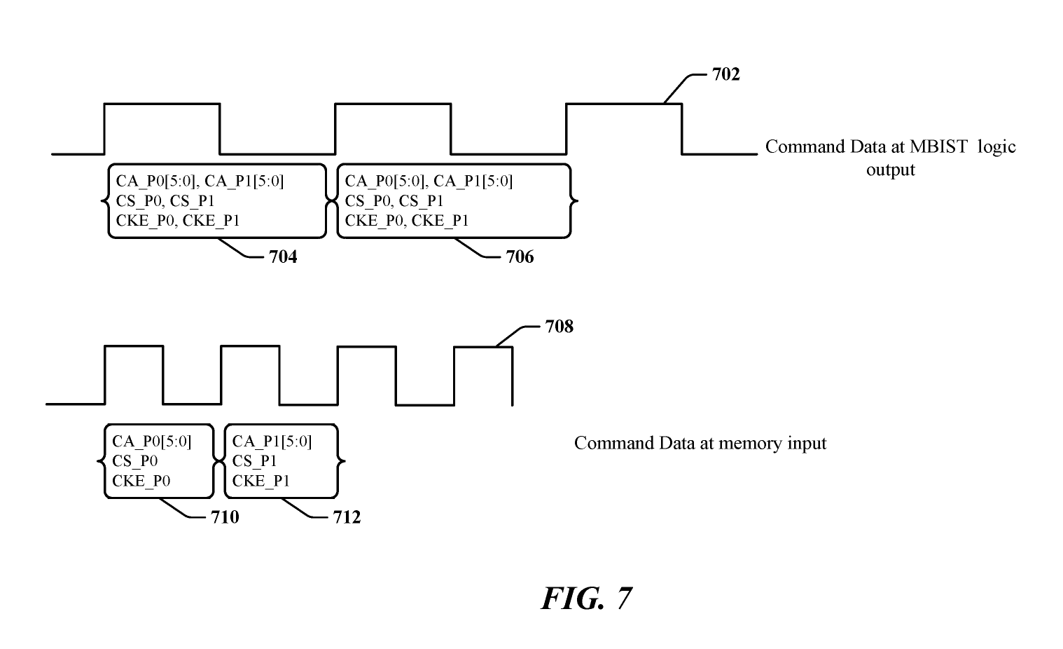

FIG. 7 illustrates a timing diagram of command data (e.g., CA/CS/CKE signals) at the MBIST logic output and at an input of the memory (or memory interface) where the timing frequency of the MBIST logic and signals for testing the memory is some fraction of the memory operating frequency. As illustrated, a clock 702 for the operation of the MBIST logic 112 operates at a particular frequency or clock cycle length. As may be seen, the command data 704 or 706 for first and second phases (P0, P1) is generated over a full cycle of the clock 702. As discussed above, however, the frequency of clock 702 at which the MBIST operates is lower than the operating frequency of the DDR memory devices, and in some aspects, is equal to the memory controller (MC) or BIMC clock.

After translation of MBIST signals of the MBIST logic 112 to be compatible with the memory interface (and memory devices), the DDR operating frequency is higher than the BIMC clock. In this example, the clock or operating frequency of clock 708 of the DDR memory devices is approximately twice that of the BIMC clock frequency of clock signal 702. Because the MBIST logic 112, or portions thereof including the interface, operates at approximately half of the frequency of the DDR memories (e.g., the DDR memory interface) and the CA operation is at Single Data rate (SDR) at the DDR memory, the MBIST logic needs to provide double the data for every MBIST logic clock cycle. Thus, the command data for phases P0 and P1 that was generated over a cycle of the MBIST clock 702 now is transmitted over two cycles of the clock 708 at which the DDR memories operate. Accordingly, the first phase P0 command data 710 is transmitted over a first cycle of the clock 708 and the second phase P1 command data 712 is transmitted over the next second cycle of clock 708. Accordingly, the present methods and apparatus provide for approximately 1:2 frequency support in the example of FIG. 7. It is noted, however, that the present disclosure is not limited to only 1:2 frequency support and other ratios may be contemplated to be within the scope of the present disclosure.

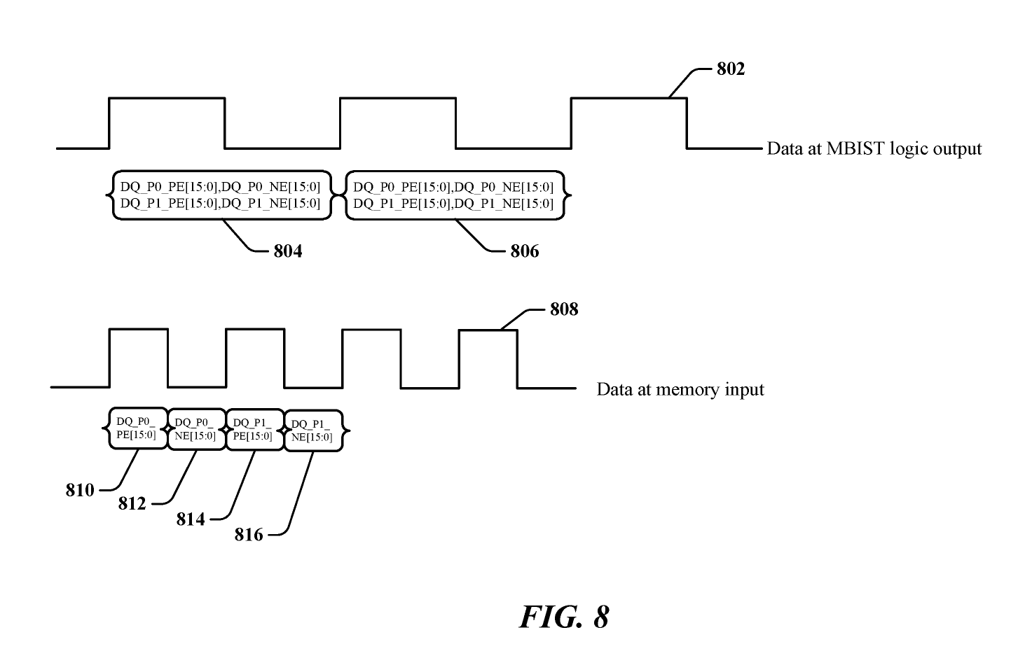

FIG. 8 illustrates a timing diagram of DQ/DQS data within the MBIST logic and at an input of the memory where the timing frequency of the MBIST is a fraction of the memory operating frequency. Given the example of FIG. 7, if the MBIST logic (e.g., the interface of the MBIST logic) operates at a frequency that is approximately half of the frequency of DDR memory device and data operation is at Double Data rate (DDR) at the DDR memory, the MBIST logic will need to provide Four Word data at every cycle of the MBIST clock 802. As illustrated, this four word data is illustrated by data 804 or 806, and is data for both phase 0 and phase 1 modes (P0 and P1).

At the memory input, however, two data words are transmitted for each cycle of the DDR clock 808. Thus, the DQ for phase P0 is transmitted in the first cycle as shown by 810 and 812, and the DQ for phase P1 is transmitted over a second, subsequent cycle as may be seen by data 814 and 816.

Of further note, the strobe DQS consists of writeable signals and may be transported with write data on DDR bus. The Timing of DQ verses DQS may be taken care by the translation FSM according to some configurations.

Because of the feature of the approximately 1:2 BIMC/DDR ratio discussed above, another aspect of the present disclosure is provision of phase control support to support phase control for CA/DQ/IE (input enable)/OE

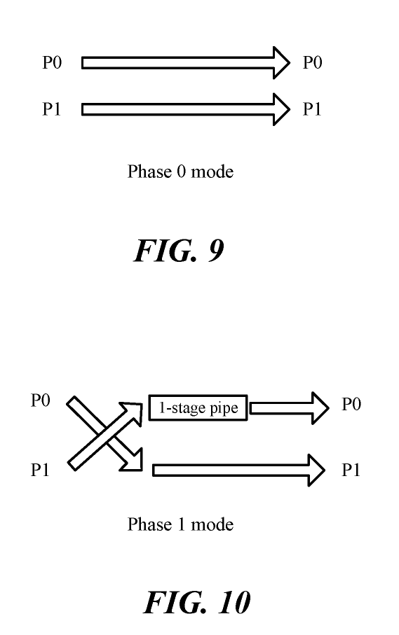

9output enable) buses. As the BIMC is operating at a frequency that is approximately half the frequency of DDR, there is a requirement to support the launch of commands and data on either of the P0 and P1 phases. Accordingly, the present disclosure provides for a phase support module in the MBIST logic (See e.g., phase control logic or module 412 in FIG. 4 as exemplary) to enable shifting of data/command/IE/OE, etc. by approximately one half cycle of the BIMC clock (or a full cycle of DDR DRAM clock), for example. As may be seen in FIG. 9, when commands and data are launched on a phase P0, then no shifting is necessary. However, when launch of commands or data start during phase 1, the phase 0 (P0) data is switched for transmission first, and the phase 1 (P1) is delayed or shifted a half cycle in a single state pipe, for example, for transmission during the next phase mode (e.g., P0) as is illustrated in FIG. 10.

According to another aspect of the present disclosure, a mask control functionality and/or logic (See e.g., exemplary logic 414 in FIG. 4) is providing to support several data mask (DM) sequence options for different MBIST algorithms that may be executed (e.g., DM sequences 0101-0101, 0011-0011, 0110-0110, or 0101-1010). In a particular example, MBIST native support of oddgroup-writeenable and evengroup-writeenable command has been modified to support the several different data mask algorithms According to an embodiment, the mask control feature is achieved by smart swapping of the DM bus while integrating it within the BIMC system. According to another aspect, the mask controls may be configured to user selectable

According to yet another aspect of the previous disclosure, rather than rely upon hard-coded latencies used for each operation set for every frequency of operation, the present disclosure provides a programmable latency control for one or more signals (See e.g., exemplary control block 416 in FIG. 4). In an aspect, programmable latency control may be provided for one or more of the following signals: write latency; Read (rd_traffic etc.) Latency; Read_enable latency; IE/OE programmable latency with phase control; programmable data polarity latency; Inhibit_data compare, or Expect_data command select, and Strobe latency, as a few examples. It is noted that hard-coded latencies in previously known systems resulted in a huge operation set area. The present programmable latency control affords a reduction of approximately 30% of the operation set area. Furthermore, it is noted that the programmable latency control affords the ability to support a number of different latencies, including JEDEC latencies.

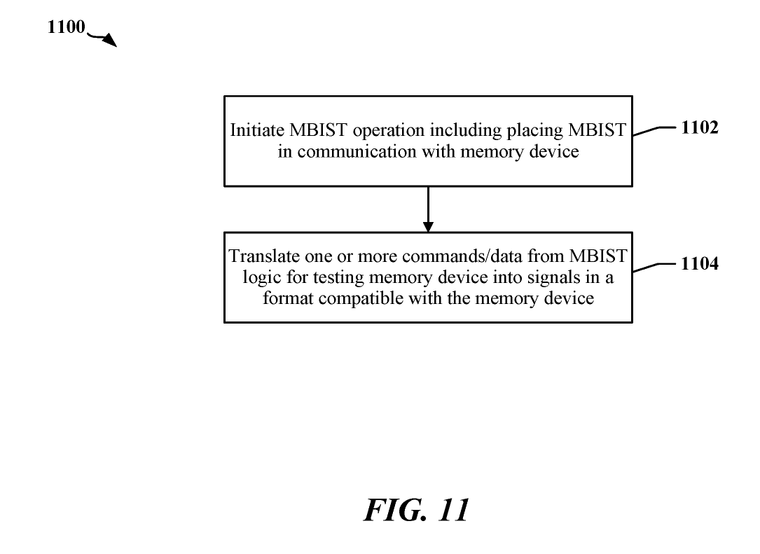

FIG. 11 illustrates an exemplary method 1100 for implementing and operating an MBIST in a BIMC. As illustrated, method 1100 includes initiating an MBIST operation in the BIMC as illustrated in block 1102. The initiating process of block 1102 may include placing or generating MBIST logic (e.g., 302 in FIG. 3) and connecting the MBIST logic or placing the MBIST logic in communication with a memory device or memory interface (e.g., 104 and 206). The processes of block 1102 may be effectuated by the BIMC 102, as well as other controllers or logic for issuing BIST enable signal 310, as one example.

Method 1100 further includes translating one or more commands and data from the MBIST logic with a memory translation logic (e.g., 410, 500, 600) into signals in a format that are compatible with a DDR memory/memory interface when testing a memory device as shown in block 1104.

Furthermore, method 1100 may further include the MBIST logic configured to operate at a frequency of the MC or BIMC, wherein the frequency of the MC operation is less than the operating frequency of the at least memory device and, in an aspect, the MBIST logic (e.g., 112 or component logic thereof) is configured to receive the signals for testing at a frequency that is less than the operating frequency of the memory device. In a particular aspect, the frequency of operation of the BIMC and MBIST logic is approximately one half of the operating frequency of the at least one memory device. When the operating frequency of the BIMC and MBIST is half the frequency of the memory device, the MBIST logic is further configured to provide approximately two times the data at an output of the MBIST of a normal output to the at least one memory device for each BIMC clock cycle. The data output by the MBIST logic may include one or more of CA, CKE, CS/, DQ, or DQS signaling.

According to another aspect, the MBIST logic may be configured to be incorporated into a conventional BIMC, thus avoiding the need for a customized BIMC. As described before, this may be accomplished by the use of software tools that are capable of configuring the internal BIMC logic/circuitry to configure or for the MBIST logic. According to a further aspect, the disclosed translation is further performed with a memory translation logic or memory representation that includes the use of a finite state machine (FSM) including a translation logic configured to translate commands and data to a format compatible with the memory device and a memory interface coupled between the MBIST logic and the memory device.

In still another aspect, the MBIST logic may further comprise a phase control support logic configured to launch at least one of a command or data on either of a first phase mode or a second phase mode, the phase control support logic including a swapping mechanism configured to shift both data and CA buses approximately one half of a BIMC clock cycle. In yet another aspect, the MBIST logic further includes a data mask control logic configured for programmable selection of a data mask (DM) sequence dependent upon specific algorithms configured for the type of the at least one memory device. The data mask control logic may be further configured to use a groupwrite-enable and a swapping mechanism to achieve different DM sequences required for custom algorithms.

In still another aspect, the MBIST logic may further include a programmable latency control logic configured to provide latency control for one or more signals in the MBIST. It is noted that the one or more signals comprise one or more of write, read, Read_enable, IE/OE programmable latency with phase control, programmable data polarity latency, Inhibit_data compare, data command select, and strobe latency signals. In yet one further aspect, the MBIST logic may further comprise a memory representation logic configured to simulate a local memory device to the MBIST logic.

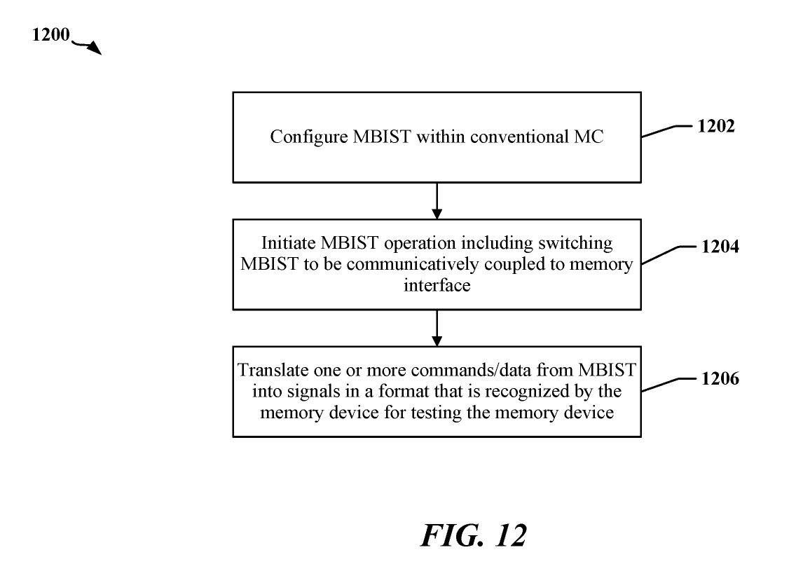

FIG. 12 illustrates a flow diagram of another exemplary method 1200 for implementing an MBIST in a BIMC. In method 1200, a first process 1202 includes first configuring an MBIST within a conventional BIMC, such as with a memory configuration tool or software/firmware to effectuate the MB SIT logic including logic such as one or more of an MBIST controller 402, an MBIST interface logic 404, and a memory representation 406, as well as an interface for external instructions such as TAP 408 coupling to a JTAG interface 316. Furthermore, the MBIST configuration may include configuration of the FSM and translation logic 410 within the memory representation 406.

After configuration of the MBIST in block 1202, method 1200 further includes initiating MBIST operation including switching the MBIST to be communicatively coupled to a memory interface as shown at block 1204. This process in block 1204 may include BIST enabling with multiplexer 314 under control of BIST enable signal 310, as well as multiplexer 208 in memory interface 206.

Furthermore, method 1200 includes performing translation of one or more commands/data from the MBIST logic into signals that are in a format that is recognized by the memory device for testing the memory device and serve to effect memory representation including for both write and read operations.

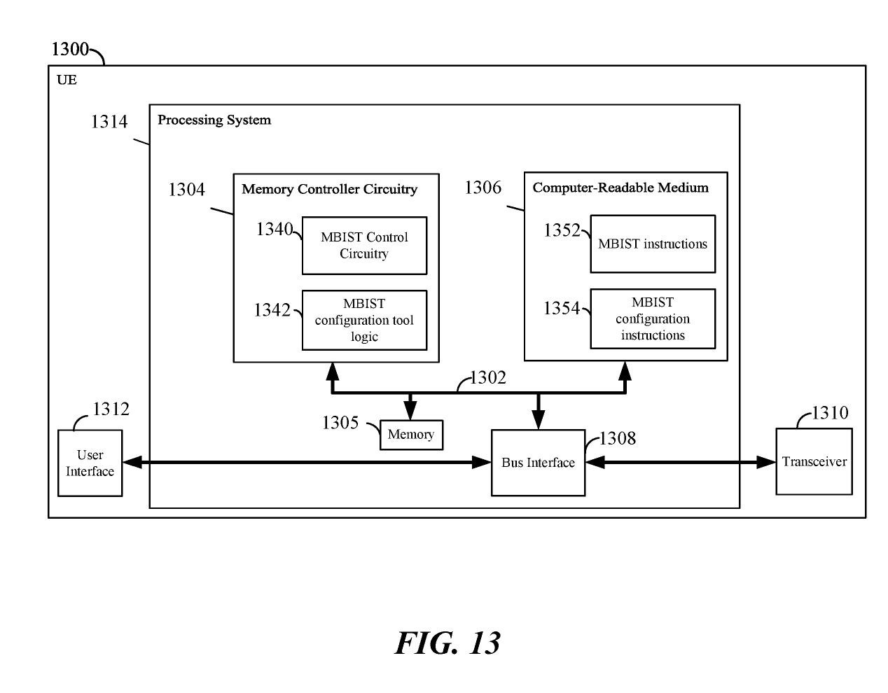

FIG. 13 is a conceptual diagram illustrating an example of a hardware implementation for an exemplary User Equipment (UE) 1300 or mobile station employing a processing system 1314. In accordance with various aspects of the disclosure, an element, or any portion of an element, or any combination of elements may be implemented with a processing system 1314 that includes one or more processors 1304. The processing system 1314 may an architecture including a bus interface 1308, a bus 1302, memory 1305 (e.g., a stacked LPDDR4 memory or memories), a processor 1304, and a computer-readable medium 1306. Furthermore, the UE 1300 may include a user interface 1312 and a transceiver 1310.

In some aspects of the disclosure, the processor 1304 may include, MBIST (and BIMC) control circuitry 1340 configured for various functions related to testing the memory 1305. For example, the circuitry 1340 may be configured to implement one or more of the functions or circuitry/logic described above in relation to FIGS. 2-12. Furthermore, one or more of processing system 1314, processor 1304, and/or MBIST control circuitry 1340, and equivalents thereof, may constitute means for setting, configuring, establishing, or determining MBIST control for testing of DDR memories.

In some other aspects of the disclosure, the processor 1304 may include, in MBIST configuration logic or circuitry 1342 configured for various functions related to configuring the MBIST. For example, the circuitry 1340 may be configured to implement one or more of the functions or circuitry/logic described above in relation to FIGS. 2-12. Furthermore, one or more of processing system 1314, processor 1304, and/or MBIST configuration logic 1342, and equivalents thereof, may constitute means for setting, configuring, establishing, or determining MBIST control for testing of DDR memories.

One or more processors 1304 in the processing system 1314 may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium 1306. The computer-readable medium 1306 may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium 1306 may reside in the processing system 1314, external to the processing system 1314, or distributed across multiple entities including the processing system 1314. The computer-readable medium 1306 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

In one or more examples, the computer-readable storage medium 1306 may include software or code 1352 configured for various functions, including, for example, setting, configuring, establishing, or determining MBIST testing of DDR memories, such as stacked LPDDR4 memories. For example, the software or code 1352 may be configured to implement one or more of the functions described above in relation to FIG. 2-12, including, e.g., block 1104 in FIG. 11.

The medium 1306 may also include software or code 1354 configured for various functions, including, for example, setting, configuring, or establishing, the MBIST controller. For example, the software or code 1354 may be configured to implement one or more of the functions described above in relation to FIG. 2-12, including, e.g., block 1202 in FIG. 12.

In other aspects, an apparatus that may be implemented in UE 1300 may include a memory (e.g., 1305) receiving one or more instructions for testing the memory, with the instructions including a command for initiating an MBIST operation within a memory controller (MC) including placing an MBIST logic in communication with the memory device. Further, the instruction may include a command for translating one or more commands and data from the MBIST logic with a memory translation logic for testing the memory device into signals in a format that are compatible with the memory device.

In light of the foregoing, those skilled in the art will appreciate that the presently disclosed methods and apparatus provide a memory test controller design that enables and supports extensive algorithm testing of stacked memories, and LPDDR4 memories in a particular example wherein the memory test controller may be added to existing designs with minimal modification. Further, due to use of the translation FSM and MBIST to memory decoder as discussed above, the DDR compatible operations are supportable using the MBIST. Still further, split LPDDR4 commands may be easily supported. (e.g., activate-1-activate-2, Write-1-cas-2, etc.). Additionally in the case of LPDDR4 specific operations like the data bus inversion (DBI) feature, or supplier specific testmodes and operations like die-id read may be easily supported with the present methods and apparatus.

Moreover, those skilled in the art will appreciate that calibration related LPDDR4 operations may be supported (e.g., DQ Calibration, DQ latching, MPC calibration, etc.). Also byte specific MRR read is enabled.

One or more of the components, steps, features, and/or functions illustrated in FIGS. 2, 3, 4, 5, 6, 11 and/or 12 may be rearranged and/or combined into a single component, step, feature or function or embodied in several components, steps, or functions. Additional elements, components, steps, and/or functions may also be added without departing from the invention.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described in the figures. The novel algorithms described herein may also be efficiently implemented in software and/or embedded in hardware.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another, even if they do not directly physically touch each other.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Moreover, a storage medium may represent one or more devices for storing data, including read-only memory (ROM), random access memory (RAM), magnetic disk storage mediums, optical storage mediums, flash memory devices and/or other machine readable mediums for storing information. The terms “computer-readable medium,” “machine readable medium,” or “machine readable storage medium” include, but are not limited to portable or fixed storage devices, optical storage devices, wireless channels and various other mediums capable of storing, containing or carrying instruction(s) and/or data. Furthermore, in aspects of the present disclosure, a non-transitory computer-readable medium storing computer-executable code may be provided. Such code may be configured for causing a computer to: implement within a memory controller (MC) a memory built-in self-test (MBIST) function or equivalent logic functionality configured for testing at least one memory device. Further, the code may cause a computer translate, using the MBIST function, signals for testing the at least one memory device into signals in a format that is used by the at least one memory device.

Furthermore, embodiments may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits (e.g., processing circuit), elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing components, e.g., a combination of a DSP and a microprocessor, a number of microprocessors, one or more microprocessors in conjunction with a DSP core, or any other such configuration.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus comprising:
a memory controller (MC) comprising:
a memory built-in self-test (MBIST) controller configured for testing at least one memory device, wherein the MBIST includes:
a memory translation logic configured to translate signals for testing the at least one memory device into signals in a format of the at least one memory device.

2. The apparatus of claim 1, wherein the MBIST controller is further configured to receive the signals for testing at a frequency less than the operating frequency of the at least memory device.

3. The apparatus of claim 2, wherein the signals for testing frequency are approximately one half of the operating frequency of the at least one memory device or a memory interface of the at least one memory device.

4. The apparatus of claim 3, wherein the MBIST controller is configured to provide approximately two times the data at an output of the MBIST logic to the at least one memory device for each MC clock cycle.

5. The apparatus of claim 4, wherein the data output by the MBIST controller includes one or more of Command Address (CA), clock enable (CKE), Chip select (CS), data (DQ), or data strobe (DQS) signaling.

6. The apparatus of claim 1, wherein the memory translation logic comprises a finite state machine (FSM) including a translation logic configured to translate commands and data to a format compatible with the memory device and a memory interface coupled between the MBIST and the memory device.

7. The apparatus of claim 1, the MBIST controller or logic further comprising:
a phase control support logic configured to launch at least one of a command or data on either of a first phase mode or a second phase mode, the phase control support logic including a swapping mechanism configured to shift both data and CA buses approximately one half of a MC clock cycle.

8. The apparatus of claim 1, the MBIST further comprising:
a data mask control logic configured for programmable selection of a data mask (DM) sequence dependent upon specific algorithms configured for the type of the at least one memory device.

9. The apparatus of claim 8, wherein the data mask control logic is further configured to use a Group write-enable and swapping mechanism to achieve different DM sequences required for custom algorithms.

10. The apparatus of claim 1, the MBIST controller further comprising:
a programmable latency control logic configured to provide latency control for one or more signals in the MBIST controller.

11. The apparatus of claim 10, wherein the one or more signals comprise one or more of write, read, Read_enable, Input Enable (IE)/Output Enable (OE) programmable latency with phase control, programmable data polarity latency, Inhibit_data compare, data command select, and strobe latency signals.

12. The apparatus of claim 1, wherein the MBIST controller further comprises a memory representation logic configured to simulate a local memory device to the MBIST controller.

13. The apparatus of claim 1, wherein the apparatus further comprises:
a host incorporating the MC.

14. The apparatus of claim 13, comprising
the at least one memory;
a communicative coupling, wherein the communicative coupling configured to communicate the signals for testing the at least one memory device tithe at least one memory.

15. The apparatus of claim 14, further comprising
one of a mobile phone and a mobile communicating device, incorporating the host, the communicative coupling, and the at least one memory.

16. A method for testing a memory device, comprising:
initiating an MBIST operation within a memory controller (MC) including placing an MBIST logic in communication with the memory device; and
translating one or more commands and data from the MBIST logic with a memory translation logic for testing the memory device into signals in a format that are compatible with the memory device.

17. The method of claim 16, wherein the MBIST logic is further configured to operate at a frequency of the MC, wherein the frequency of the MC operation is less than the operating frequency of the at least memory device or a memory interface of the at least one memory device.

18. The method of claim 16, wherein the frequency of operation of the MC and MBIST logic is approximately one half of the operating frequency of the at least one memory device.

19. The method of claim 18, wherein the MBIST logic is configured to provide approximately two times the data at an output of the MBIST logic to the at least one memory device for each MC clock cycle.

20. The method of claim 19, wherein the data output by the MBIST logic includes one or more of CA, CKE, CS, DQ, or DQS signaling.

21. The method of claim 16, wherein the MBIST logic is configured to be incorporated into a conventional BIMC.

22. The method of claim 16, wherein the translation is performed with a memory translation logic that comprises a finite state machine (FSM) including a translation logic configured to translate commands and data to a format compatible with the memory device and a memory interface coupled between the MBIST logic and the memory device.

23. The method of claim 16, the MBIST logic further comprising:
a phase control support logic configured to launch at least one of a command or data on either of a first phase mode or a second phase mode, the phase control support logic including a swapping mechanism configured to shift both data and CA buses approximately one half of an MC clock cycle.

24. The method of claim 16, the MBIST logic further comprising:
a data mask control logic configured for programmable selection of a data mask (DM) sequence dependent upon specific algorithms configured for the type of the at least one memory device.

25. The method of claim 16, the MBIST logic further comprising:
a programmable latency control logic configured to provide latency control for one or more signals in the MBIST logic.

26. The method of claim 16, wherein the MBIST logic further comprises a memory representation logic configured to simulate a local memory device to the MBIST logic.

27. An apparatus, comprising
a memory receiving one or more instructions for testing the memory, the instructions comprising:
a command for initiating an MBIST operation within a memory controller (MC) including placing an MBIST logic in communication with the memory device; and
a command for translating one or more commands and data from the MBIST logic with a memory translation logic for testing the memory device into signals in a format that are compatible with the memory device.

28. The apparatus of claim 27, wherein the MBIST operation is further configured to receive the signals for testing at a frequency less than the operating frequency of the at least memory device.

29. A non-transitory computer-readable medium storing computer-executable code, comprising code for causing a computer to:
implement within a memory controller (MC) a memory built-in self-test (MBIST) function configured for testing at least one memory device; and
translate, using the MBIST function, signals for testing the at least one memory device into signals in a format that is used by the at least one memory device.

30. The non-transitory computer-readable medium of claim 29, further comprising code for causing a computer to receive the signals for testing at a frequency less than the operating frequency of the at least memory device.
